(19) United States
(12) Patent Application Publication
(10) Pub. No.: US 2015/0195905 A1
(43) Pub. Date: Jul. 9, 2015

(54) PACKAGE BOARD, METHOD OF MANUFACTURING THE SAME, AND SEMICONDUCTOR PACKAGE USING THE SAME

(71) Applicant: SAMSUNG ELECTRO-MECHANICS CO., LTD., Suwon-Si (KR)

(72) Inventors: Myung Sam KANG, Suwon-Si (KR); Seung Eun LEE, Suwon-si (KR); Seung Yeop KOOK, Suwon-si (KR); Ki Jung SUNG, Suwon-Si (KR); Ju Hee PARK, Suwon-Si (KR); Je Gwang YOO, Suwon-Si (KR); Jin Seon PARK, Suwon-Si (KR)

(73) Assignee: SAMSUNG ELECTRO-MECHANICS CO., LTD., Suwon-Si (KR)

(21) Appl. No.: 14/457,109

(22) Filed: Aug. 11, 2014

(30) Foreign Application Priority Data
Jan. 3, 2014 (KR) 10-2014-0000848

(51) Int. Cl. H05K 1/02; H05K 1/16; H01G 4/00; H05K 1/03; H05K 3/02; H05K 3/46; H05K 1/18; H05K 1/11

(52) U.S. Cl. CPC H05K 1/0298; H05K 1/185; H05K 1/162; H05K 1/115; H05K 1/0313; H05K 3/02; H05K 3/4644; H01G 4/00; H05K 2201/10159; H05K 2203/02; H05K 2203/1453

(57) ABSTRACT

There are provided a package board, a method of manufacturing the same, and a semiconductor package using the same. According to an exemplary embodiment of the present disclosure, the package substrate may include: an insulating layer; a circuit layer formed on and beneath the insulating layer; a capacitor formed in the insulating layer and including an upper electrode, a lower electrode, and a dielectric layer formed between the upper electrode and the lower electrode; and a via connecting the circuit layer to the upper electrode and the lower electrode.

### CROSS-REFERENCE TO RELATED APPLICATION

This application claims the foreign priority benefit of Korean Patent Application No. 10-2014-0000848, filed on Jan. 3, 2014, entitled “Package Board, Method Of Manufacturing The Same, And Semiconductor Package Using The Same” which is hereby incorporated by reference in its entirety into this application.

### BACKGROUND

Embodiments of the present invention relate to a package board, a method of manufacturing the same, and a semiconductor package using the same.

With the rapid development of a semiconductor technology, a semiconductor device is remarkably growing. Further, the development for a semiconductor package such as a system in package (SIP), a chip sized package (CSP), and a flip chip package (FCP) configuring as a package by mounting an electronic device such as the semiconductor device on a printed circuit substrate in advance has been actively conducted. Further, to implement miniaturization and improvement in performance of a high-performance smart phone, there is a package on package (POP) in which a control device and a memory device are implemented as one package form. The package on package may be implemented by individually packaging the control device and the memory device and stacking and connecting them.

### RELATED ART DOCUMENT

### Patent Document

(Patent Document 1) U.S. Pat. No. 5,986,209

### SUMMARY

An aspect of the present disclosure may provide a package substrate capable of shielding signal noises, a method of manufacturing the same, and a semiconductor package using the same.

Another aspect of the present disclosure may provide a package substrate capable of reducing reactance, a method of manufacturing the same, and a semiconductor package using the same.

Still another aspect of the present disclosure may provide a package substrate capable of reducing a thickness, a method of manufacturing the same, and a semiconductor package using the same.

Still yet another aspect of the present disclosure may provide a package substrate capable of reducing process cost and time by simultaneously forming a capacitor and a circuit layer, a method of manufacturing the same, and a semiconductor package using the same.

According to an aspect of the present disclosure, a package substrate may include: an insulating layer; a circuit layer formed on and beneath the insulating layer; a capacitor formed in the insulating layer and including an upper electrode, a lower electrode, and a dielectric layer formed between the upper electrode and the lower electrode; and a via connecting the circuit layer to the upper electrode and the lower electrode.

The insulating layer may have a 2-layer structure and may include a first insulating layer and a second insulating layer formed on the first insulating layer and the circuit layer may have a 3-layer structure and may include a first circuit layer formed on the first insulating layer, a second circuit layer formed beneath the first insulating layer, and a third circuit layer formed on the second insulating layer.

The capacitor may be formed on the first insulating layer and may be embedded in the second insulating layer. [ 0011] The via may include: a first via formed on the first insulating layer to connect the lower electrode of the capacitor to the second circuit layer; and a second via formed on the second insulating layer to connect the upper electrode of the capacitor to the third circuit layer.

One of the first circuit layer to the third circuit layer may be a ground layer and another layer may be a power layer.

The package substrate may further include: a solder resist layer formed to enclose the insulating layer and the circuit layer, except for an area connected to the outside from the circuit layer.

According to another aspect of the present disclosure, a method of manufacturing a package substrate may include: preparing a carrier substrate; forming a first insulating layer on the carrier substrate; forming a first metal layer on the first insulating layer; forming a dielectric layer on the first metal layer; forming a second metal layer on the first metal layer and the dielectric layer; forming a first circuit layer and a capacitor by patterning the first metal layer and the second metal layer; forming a second insulating layer on the first insulating layer, a circuit layer, and an upper portion of the capacitor; removing the carrier substrate; forming a first via penetrating through the first insulating layer to be connected to the capacitor and a second via penetrating through the second insulating layer to be connected to the capacitor; and forming a second circuit layer formed beneath the first insulating layer and a third circuit layer formed on the second insulating layer.

In the forming of the second circuit layer and the third circuit layer, a circuit pattern of a portion of the second circuit layer may be connected to the first via and a circuit pattern of a portion of the third circuit layer may be connected to the second via.

One of the first circuit layer to the third circuit layer may be a ground layer and another layer may be a power layer.

The method may further include: after the forming of the second circuit layer and the third circuit layer, forming a solder resist layer enclosing the first insulating layer, the second insulating layer, the second circuit layer, and the third circuit layer, except for an area connected to an outside in the second circuit layer and the third circuit layer.

In the forming of the first circuit layer and the capacitor, the first metal layer beneath the dielectric layer may be a lower electrode of the capacitor and the second metal layer on the dielectric layer may be an upper electrode of the capacitor.

According to still another aspect of the present disclosure, a semiconductor package may include: an insulating layer; a circuit layer formed on and beneath the insulating layer; a capacitor formed in the insulating layer and including an upper electrode, a lower electrode, and a dielectric layer formed between the upper electrode and the lower electrode; a via connecting the circuit layer to the upper electrode and the lower electrode; and a semiconductor device formed on the insulating layer and electrically connected to the circuit layer.

The insulating layer may have a 2-layer structure and may include a first insulating layer and a second insulating layer formed on the first insulating layer and the circuit layer may have a 3-layer structure and may include a first circuit layer formed on the first insulating layer, a second circuit layer formed beneath the first insulating layer, and a third circuit layer formed on the second insulating layer.

The capacitor may be formed on the first insulating layer and may be embedded in the second insulating layer.

The via may include: a first via formed on the first insulating layer to connect the lower electrode of the capacitor to the second circuit layer; and a second via formed on the second insulating layer to connect the upper electrode of the capacitor to the third circuit layer.

One of the first circuit layer to the third circuit layer may be a ground layer and another layer may be a power layer.

The semiconductor package may further include: a solder resist layer formed to enclose the insulating layer and the circuit layer, except for an area connected to the outside in the circuit layer.

The semiconductor device may be a memory device.

The semiconductor package may further include: a molding part formed to enclose the insulating layer, the circuit layer, the capacitor, and the semiconductor device.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplified view illustrating a package substrate according to an exemplary embodiment of the present disclosure;

FIGS. 2 through 16 are exemplified views illustrating a method of manufacturing a package substrate according to the exemplary embodiment of the present disclosure; and

FIG. 17 is an exemplified view illustrating a semiconductor package to which the package substrate according to the exemplary embodiment of the present disclosure is applied.

### DESCRIPTION OF EMBODIMENTS

The aspects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

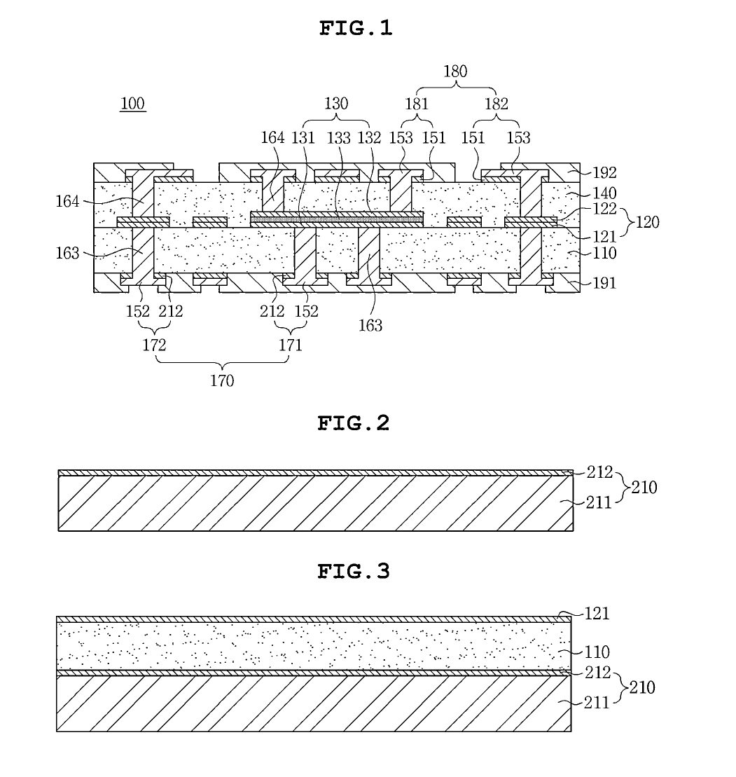

FIG. 1 is an exemplified view illustrating a package substrate according to an exemplary embodiment of the present disclosure.

Referring to FIG. 1, a package substrate 100 according to an exemplary embodiment of the present disclosure may include a first insulating layer 110, a second insulating layer 140, a first circuit layer 120 to a third circuit layer 180, a capacitor 130, a first via 163, a second via 164, a first solder resist layer 191, and a second solder resistor layer 192.

According to the exemplary embodiment of the present disclosure, the first insulating layer 110 and the second insulating layer 140 may be generally made of a composite polymer resin used as an interlayer insulating material. For example, the first insulating layer 110 and the second insulating layer 140 may be made of an epoxy based resin, such as a prepreg, an ajinomoto build up film (ABF), FR-4, and bismaleimide triazine (BT). However, according to the exemplary embodiment of the present disclosure, a material forming the first insulating layer 110 and the second insulating layer 140 is not limited thereto. The first insulating layer 110 and the second insulating layer 140 according to the exemplary embodiment of the present disclosure may be selected from the insulating materials known in a circuit board field.

According to the exemplary embodiment of the present disclosure, the second insulating layer 140 may be formed on the first insulating layer 110.

According to the exemplary embodiment of the present disclosure, the first circuit layer 120 may be formed on the first insulating layer 110.

According to the exemplary embodiment of the present disclosure, the second circuit layer 170 may be formed beneath the first insulating layer 110. According to the exemplary embodiment of the present disclosure, the second circuit layer 170 may include a second circuit pattern 171 and an external connection pad 172. The package substrate 100 according to the exemplary embodiment of the present disclosure may be electrically connected to another semiconductor package through the external connection pad 172.

According to the exemplary embodiment of the present disclosure, a third circuit layer 180 may be formed on the second insulating layer 140. According to the exemplary embodiment of the present disclosure, the third circuit layer 180 may include a third circuit pattern 181 and a bonding bad 182. The bonding pad 182 may be electrically connected to a semiconductor device (not illustrated) when the semiconductor device (not illustrated) is mounted on the package substrate 100. For example, the bonding pad 182 may be connected to the semiconductor device (not illustrated) by a wire bonding scheme. According to the exemplary embodiment of the present disclosure, the semiconductor device (not illustrated) mounted on the package substrate 100 may be a memory device. However, a kind of the semiconductor device (not illustrated) mounted on the package substrate 100 is not limited to the memory device.

The first circuit layer 120 to the third circuit layer 180 may be made of a conductive material. For example, the first circuit layer 120 to the third circuit layer 180 may be made of copper (Cu). However, a material forming the first circuit layer 120 to the third circuit 180 is not limited to copper. That is, any material which may be used as a conductive material for a circuit in a circuit board field may be applied to the first circuit layer 120 to the third circuit layer 180 without being limited.

Further, according to the exemplary embodiment of the present disclosure, one of the first circuit layer 120 to the third circuit layer 180 may be a power layer. Further, another layer may be a ground layer.

According to the exemplary embodiment of the present disclosure, the capacitor 130 may be a thin capacitor having a 3-layer structure. According to the exemplary embodiment of the present disclosure, the capacitor 130 may be formed on the first insulating layer 110 and may be formed to be embedded in the second insulating layer 140. The capacitor 130 according to the exemplary embodiment of the present disclosure may include an upper electrode 132, a lower electrode 131, and a dielectric layer 133. In this configuration, the dielectric layer 133 may be disposed between the upper electrode 132 and the lower electrode 131.

According to the exemplary embodiment of the present disclosure, the lower electrode 131 may be formed on the first insulating layer 110. That is, the lower electrode 131 and the first circuit layer 120 of the capacitor 130 may be formed on the same layer. Further, the lower electrode 131 of the capacitor 130 may be formed to be partially bonded to the first circuit layer 120. For example, when the first circuit layer 120 is the power layer, the lower electrode 131 of the capacitor 130 may also serve as the power layer.

According to the exemplary embodiment of the present disclosure, the lower electrode 131 and the upper electrode 132 of the capacitor 130 may be made of the conductive material. For example, the lower electrode 131 and the upper electrode 132 may be made of copper (Cu). However, the material forming the lower electrode 131 and the upper electrode 132 is not limited to copper, and therefore any conductive material which may be used in the circuit board field may be applied to the lower electrode 131 and the upper electrode 132 without being limited. The package substrate 100 according to the exemplary embodiment of the present disclosure may have the capacitor 130 embedded therein to shield noises related to electrical signal transmission to the semiconductor device (not illustrated) which is mounted later.

According to the exemplary embodiment of the present disclosure, the first via 163 may be formed to penetrate through the first insulating layer 110. According to the exemplary embodiment of the present disclosure, the first via 163 may electrically connect the lower electrode 131 of the capacitor 130 to the second circuit layer 170. Further, the first via 163 may electrically connect the first circuit layer 120 to the second circuit layer 170.

According to the exemplary embodiment of the present disclosure, the second via 164 may be formed to penetrate through the second insulating layer 140. According to the exemplary embodiment of the present disclosure, the second via 164 may electrically connect the upper electrode 132 of the capacitor 130 to the third circuit layer 180. Further, the second via 164 may electrically connect the first circuit layer 120 to the third circuit layer 180.

The first via 163 and the second via 164 according to the exemplary embodiment of the present disclosure may be made of the conductive material. For example, the first via 163 and the second via 164 may be made of copper (Cu). However, the material forming the first via 163 and the second via 164 is not limited to copper, and therefore any material which may be used as the conductive material for the circuit in the circuit board field may be applied to the first via 163 and the second via 164 without being limited.

As such, in the package substrate 100 according to the exemplary embodiment of the present disclosure, the capacitor 130 may be connected to the plurality of first vias 163 and second vias 164. As such, the capacitor 130 may be connected to the plurality of vias, and thus reactance may be reduced. Therefore, noise shielding characteristics for an electronic signal may be improved.

A first solder resist layer 191 and a second solder resist layer 192 according to the exemplary embodiment of the present disclosure may be formed to protect an outer layer of the package substrate 100. For example, the first solder resist layer 191 and the second solder resist layer 192 may be formed to prevent solder from applying on the circuit layer or the circuit layer from oxidizing while external components are mounted on the outer layer of the package substrate 100. Here, the external components may be components which may be electrically connected to the package substrate 100 according to the exemplary embodiment of the present disclosure such as the semiconductor device, the substrate, and the semiconductor package. The first solder resist layer 191 and the second solder resist layer 192 may be made of a heat resistant covering material.

The first solder resist layer 191 may be formed beneath the first insulating layer 110. Further, the first solder resist layer 191 may be formed to enclose the second circuit layer 170 except for an area connected to the outside. Here, the area connected to the outside may be the external connection pad 172.

The second solder resist layer 192 may be formed on the second insulating layer 140. Further, the second solder resist layer 192 may be formed to enclose the third circuit layer 180 other than the area connected to the outside. Here, the area connected to the outside may be the bonding pad 182.

The package substrate 100 according to the exemplary embodiment of the present disclosure may have the capacitor 130 which is connected to the plurality of vias, embedded therein, and thus both of the noise shielding and the reduction in reactance may be implemented. Therefore, the noise shielding characteristics for an electronic signal may be improved.

The exemplary embodiment of the present disclosure describes, by way of example, that the package substrate 100 is provided with the insulating layer having a 3-layer structure and the circuit layer having a two-layer structure, but is not limited thereto. That is, the number of layers of the package substrate 100 may be variously implemented according to the selection of those skilled in the art.

FIGS. 2 to 15 are exemplified views illustrating a method of manufacturing a package substrate according to the exemplary embodiment of the present disclosure.

Referring to FIG. 2, a carrier substrate 210 may be prepared.

According to the exemplary embodiment of the present disclosure, the carrier substrate 210 may be formed by disposing a carrier metal layer 212 on a carrier core 211.

When the insulating layer, the circuit layer, and the like are formed on the package substrate, the carrier core 211 is to support the insulating layer, the circuit layer, and the like. The carrier substrate 211 may be removed later in the middle step while the package substrate is formed or after the package substrate is formed. The carrier core 211 may be made of an insulating material or a metal material. Alternately, the carrier core 211 may be a copper clad laminate. However, the carrier core 211 is not limited thereto, but any kind of carrier among the carriers which are used as a support substrate in the circuit board field and removed later may be applied to the carrier core 211.

According to the exemplary embodiment of the present disclosure, the carrier metal layer 212 may be made of copper. However, the material of the carrier metal layer 212 is not limited to copper, and therefore any material which may be used as the conductive material for the circuit in the circuit substrate field may be applied to the carrier metal layer 212 without being limited.

The exemplary embodiment of the present disclosure describes that the carrier substrate 210 includes the carrier metal layer 210, but is not limited thereto. For example, the carrier substrate 210 may be configured only of the carrier core 211. According to the exemplary embodiment of the present disclosure, the carrier metal layer 212 is formed on the carrier core 211, thereby preparing the carrier substrate 210 according to the exemplary embodiment of the present disclosure.

Referring to FIG. 3, the first insulating layer 110 and the first metal layer 121 may be formed on the carrier substrate 210.

According to the exemplary embodiment of the present disclosure, the first insulating layer 110 may be formed on the carrier metal layer of the carrier substrate 210.

The first insulating layer 110 may be generally made of the composite polymer resin used as the interlayer insulating material. For example, the first insulating layer 110 may be made of an epoxy based resin, such as prepreg, ajinomoto build up film (ABF), FR-4, and bismaleimide triazine (BT). However, according to the exemplary embodiment of the present disclosure, the material forming the first insulating layer 110 is not limited thereto. The first insulating layer 110 according to the exemplary embodiment of the present disclosure may be selected from insulating materials known in the circuit board field.

According to the exemplary embodiment of the present disclosure, the first metal layer 121 may be formed on the first insulating layer 110. For example, the first metal layer 121 may be made of copper. However, the material of the first metal layer 121 is not limited to copper, and therefore any material which may be used as the conductive material for the circuit in the circuit substrate field may be applied to the first metal layer 121 without being limited. The first metal layer 121 may be formed by an electroless plating method and an electroplating method. Alternatively, the first metal layer 121 may be formed by a lamination method. A method of forming a first metal layer 121 is not limited to the foregoing method, and therefore any method which may form the metal layer on the insulating layer in the circuit board field may be applied.

According to the exemplary embodiment of the present disclosure, the first insulating layer 110 on which the first metal layer 121 is formed in advance may be stacked on the carrier substrate 210. Alternatively, after the first insulating layer 110 is stacked on the carrier substrate 210, the first metal layer 121 may be formed on the first insulating layer 110. Alternatively, the first insulating layer 110 and the first metal layer 121 may be simultaneously pressed while being sequentially stacked on the carrier substrate 210.

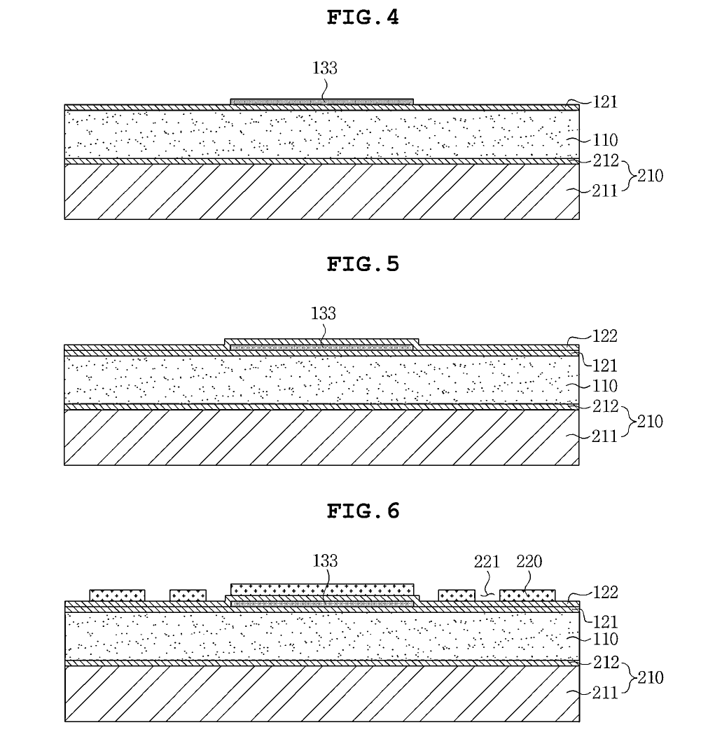

Referring to FIG. 4, the dielectric layer 133 may be formed.

According to the exemplary embodiment of the present disclosure, the dielectric layer 133 may be partially formed on the first metal layer 121. That is, the dielectric layer 133 may be formed in an area in which the capacitor (not illustrated) will be formed. The dielectric layer 133 according to the exemplary embodiment of the present disclosure may be formed on the first metal layer 121 by a method of depositing or printing a dielectric material.

Referring to FIG. 5, the second metal layer 122 may be formed.

According to the exemplary embodiment of the present disclosure, the second metal layer 122 may be formed on the first metal layer 121 and the first dielectric layer 133. For example, the second metal layer 122 may be made of copper. However, the material of the second metal layer 122 is not limited to copper, and therefore any material which may be used as the conductive material for the circuit in the circuit substrate field may be applied to the second metal layer 122 without being limited. The second metal layer 122 may be formed by the electroplating method. In this case, the first metal layer 121 may serve as a seed layer.

Referring to FIG. 6, the first etching resist 220 may be formed.

The first etching resist 220 according to the exemplary embodiment of the present disclosure may be formed on the first metal layer 121. The first etching resist 220 may include a first opening 221. The first etching resist 220 may be formed on an area in which the first circuit layer (not illustrated) and the capacitor (not illustrated) will be formed. Further, the first opening 221 of the first etching resist 220 may be formed to expose the second metal layer 122 in the area in which the first circuit layer and the capacitor will not be formed. As such, the area in which the first circuit layer and the capacitor will be formed by the first etching resist 220 may be protected from an etching process to be performed later. According to the exemplary embodiment of the present disclosure, the area in which the capacitor will be formed may be an area in which the dielectric layer 133 is formed.

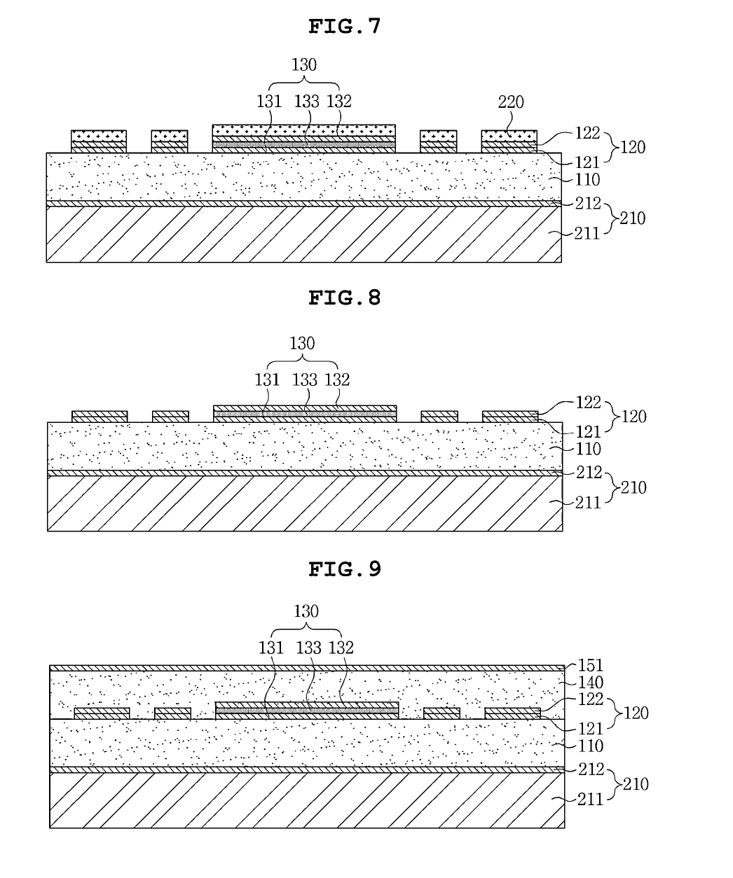

Referring to FIG. 7, the etching process may be performed.

According to the exemplary embodiment of the present disclosure, the second metal layer 122 exposed by the first etching resist 220 may be etched. In this case, the first metal layer 121 formed beneath the second metal layer 122 may also be etched simultaneously. As such, the first circuit layer 120 and the capacitor 130 may be formed by patterning the first metal layer 121 and the second metal layer 122.

The first circuit layer 120 may be formed by patterning the first metal layer 121 and the second metal layer 122 which are formed on the first insulating layer 110.

The capacitor 130 may be formed by patterning the first metal layer 121 (FIG. 6) and the second metal layer 122 (FIG. 6) in the area in which the dielectric layer 133 is formed. In this case, the first metal layer 121 (FIG. 6) beneath the dielectric layer 133 may be the lower electrode 131. Further, the second metal layer 122 (FIG. 6) on the dielectric layer 133 may be the upper electrode 132.

As such, the capacitor 130 according to the exemplary embodiment of the present disclosure may include the upper electrode 132, the lower electrode 131, and the dielectric layer 133. According to the exemplary embodiment of the present disclosure, the already completed capacitor component performed according to the prior art is not embedded in the package substrate, but the capacitor 130 may be formed simultaneously with forming the package substrate. Therefore, the package substrate is provided with a cavity to have the capacitor embedded therein, thereby more reducing the number of processes and the process time as compared with the prior art which forms the insulating layer and the circuit layer. Further, the thickness of the package substrate 100 may be reduced by forming the thin capacitor 130 having a 3-layer structure.

Referring to FIG. 8, the first etching resist 220 may be removed.

Referring to FIG. 9, the second insulating layer 140 and the third insulating layer 151 may be formed.

According to the exemplary embodiment of the present disclosure, the second insulating layer 140 is formed on the first insulating layer 110 and thus may be formed to have the first circuit layer 120 and the capacitor 130 embedded therein.

The second insulating layer 140 may be generally made of the composite polymer resin used as the interlayer insulating material. For example, the second insulating layer 140 may be made of an epoxy based resin, such as prepreg, ajinomoto build up film (ABF), FR-4, and bismaleimide triazine (BT). However, according to the exemplary embodiment of the present disclosure, the material forming the second insulating layer 140 is not limited thereto. The first insulating layer 140 according to the exemplary embodiment of the present disclosure may be selected from the insulating materials known in the circuit board field.

According to the exemplary embodiment of the present disclosure, the third metal layer 151 may be formed on the second insulating layer 140. For example, the third metal layer 151 may be made of copper. However, the material of the third metal layer 151 is not limited to copper, and therefore any material which may be used as the conductive material for the circuit in the circuit substrate field may be applied to the third metal layer 151 without being limited. The third metal layer 151 may be formed by the electroless plating method and the electroplating method. Alternatively, the third metal layer 151 may be formed by the lamination method. A method of forming a third metal layer 151 is not limited to the foregoing method, and therefore any method which may form the metal layer on the insulating layer in the circuit board field may be applied.

According to the exemplary embodiment of the present disclosure, the second insulating layer 140 on which the third metal layer 151 is formed in advance may be formed on the first insulating layer 110. Alternatively, after the second insulating layer 140 is stacked on the first insulating layer 110, the third metal layer 151 may be formed on the second insulating layer 140. Alternatively, the second insulating layer 140 and the third metal layer 151 may be pressed while being sequentially stacked on the first insulating layer 110.

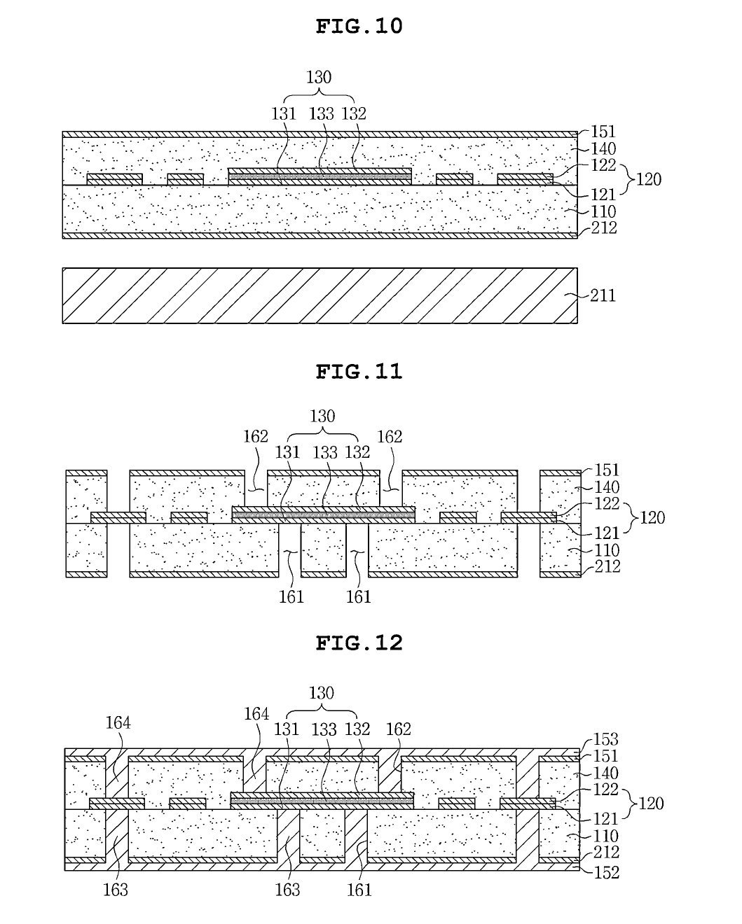

Referring to FIG. 10, the carrier core 211 may be removed.

According to the exemplary embodiment of the present disclosure, the carrier core 211 and the carrier metal layer 212 are separated from each other and thus the carrier core 211 may be removed.

In this case, the carrier metal layer 212 remains intact on the first insulating layer 110.

Referring to FIG. 11, the first via hole 161 and the second via hole 162 may be formed.

According to the exemplary embodiment of the present disclosure, the first via hole 161 may be formed to penetrate through the first insulating layer 110. In this case, the first via hole 161 may be formed to expose a lower portion of the first circuit layer 120 and the lower electrode 131 of the capacitor 130.

Further, the second via hole 162 may be formed to penetrate through the second insulating layer 140. In this case, the second via hole 162 may be formed to expose an upper portion of the first circuit layer 120 and the upper electrode 132 of the capacitor 130.

Here, the first via hole 161 and the second via hole 162 may be formed by a method of forming a via hole which is used in the circuit board field. For example, the first via hole 161 and the second via hole 162 may be formed by a laser drill.

Referring to FIG. 12, the first via 163 and the second via 164 may be formed.

The first via 163 according to the exemplary embodiment of the present disclosure may electrically connect the lower electrode 131 of the capacitor 130 or the first circuit layer 120 to the carrier metal layer 212. Further, the second via 164 may electrically connect the upper electrode 132 of the capacitor 130 or the first circuit layer 120 to the third metal layer 151.

Next, the first via hole 161 and the second via hole 162 may be filled by using the electroless plating method and the electroplating method to form the first via 163 and the second via 164.

According to the exemplary embodiment of the present disclosure, when the first via 163 is formed, a fourth metal layer 152 may be formed on the carrier metal layer 212. Further, when the second via 164 is formed, a fifth metal layer 153 may be formed on the third metal layer 151.

The fourth metal layer 152 and the fifth metal layer 153 may be simultaneously formed in the same process as that of forming the first via 163 and the second via 164. In this case, when the fourth metal layer 152 and the fifth metal layer 153 are formed by the electroplating method, the carrier metal layer 212 and the third metal layer 151 may serve as the seed layer.

Alternatively, after the first via 163 and the second via 164 are formed, the fourth metal layer 152 and the fifth metal layer 153 may be formed by a separate plating process. For example, after the first via 163 and the second via 164 are filled with a conductive paste, the fourth metal layer 152 and the fifth metal layer 153 may be formed by the electroplating method.

The exemplary embodiment of the present disclosure is not limited to the foregoing method of forming a first via 163, a second via 164, a fourth metal layer 152, and a fifth metal layer 153. That is, the first via 163, the second via 164, the fourth metal layer 152, and the fifth metal layer 153 may be formed by any of the method known in the circuit board field.

The fourth metal layer 152 and the fifth metal layer 153 may be formed to secure the thickness of the second circuit layer (not illustrated) and the third circuit layer (not illustrated) which will be formed later. Therefore, when the carrier metal layer 212 and the third metal layer 151 has a sufficient thickness to form the second circuit layer and the third circuit layer, the formation of the fourth metal layer 152 and the fifth metal layer 153 may be omitted.

For example, the first via 163, the second via 164, the fourth metal layer 152, and the fifth metal layer 153 may be made of copper. However, the material forming the first via 163, the second via 164, the fourth metal layer 152, and the fifth metal layer 153 is not limited to copper, and therefore any material which may be used as the conductive material for the circuit in the circuit board field may be applied to the material forming the first via 163, the second via 164, the fourth metal layer 152, and the fifth metal layer 153 without being limited.

According to the exemplary embodiment of the present disclosure, the plurality of first vias 163 and second vias 164 are connected to the capacitor 130, and thus the reactance may be reduced. Therefore, the noise shielding characteristics for an electronic signal may be improved.

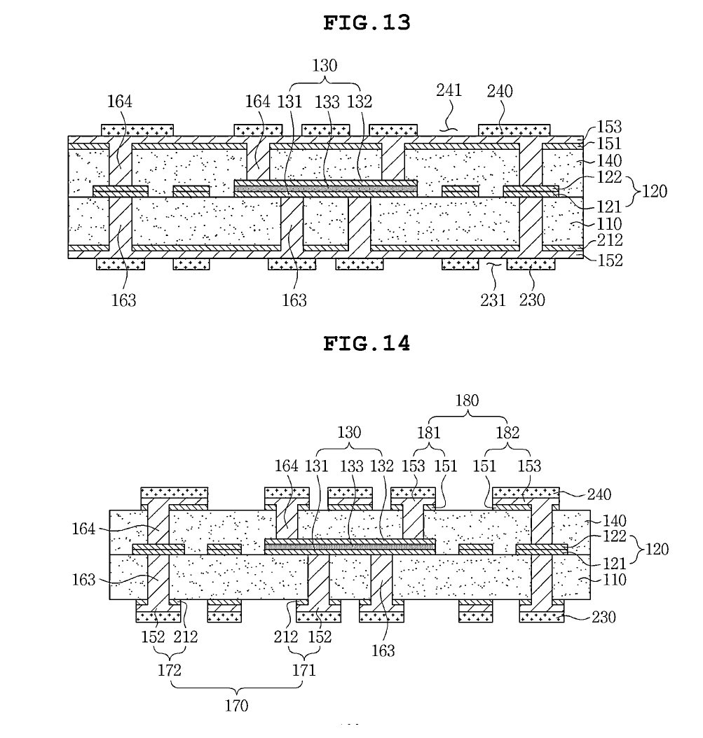

Referring to FIG. 13, a second etching resist 230 and a third etching resist 240 may be formed.

According to the exemplary embodiment of the present disclosure, the second etching resist 230 may be formed on the fourth metal layer 152. Further, the third etching resist 240 may be formed on the fifth metal layer 153.

The second etching resist 230 may include a second opening 231. The second etching resist 230 may be formed on an area in which the second circuit layer (not illustrated) will be formed. Further, the second opening 231 of the second etching resist 230 may be formed to expose the fourth metal layer 122 in the area in which the second circuit layer is not be formed.

Further, the third etching resist 240 may include a third opening 241. The third etching resist 240 may be formed on an area in which the third circuit layer (not illustrated) will be formed. Further, the third opening 241 of the third etching resist 240 may be formed to expose the fifth metal layer 153 in the area in which the third circuit layer is not be formed.

As such, the area in which the second circuit layer and the third circuit layer will be formed by the first etching resist 220 and the second etching resist 230 may be protected from the etching process to be performed later.

Referring to FIG. 14, the etching process may be performed.

According to the exemplary embodiment of the present disclosure, the fourth metal layer 152 exposed by the second etching resist 230 may be etched. In this case, the carrier metal 212 formed on the fourth metal layer 152 may also be etched simultaneously. As such, the second circuit layer 170 may be formed by patterning the fourth metal layer 152 and the carrier metal layer 212. According to the exemplary embodiment of the present disclosure, the second circuit layer 170 may include a second circuit pattern 171 and an external connection pad 172. The external connection pad 172 may be electrically connected to the package substrate 100 (FIG. 16) according to the exemplary embodiment of the present disclosure and another substrate (not illustrated) or external components such as the semiconductor package (not illustrated).

Further, the fifth metal layer 153 exposed by the third etching resist 240 may be etched. In this case, the third metal layer 153 formed beneath the fifth metal layer 151 may also be etched simultaneously. As such, the third circuit layer 180 may be formed by patterning the third metal layer 151 and the fifth metal layer 153. According to the exemplary embodiment of the present disclosure, the third circuit layer 180 may include a third circuit pattern 181 and a bonding bad 182. The package substrate 100 (FIG. 16) and the semiconductor device (not illustrated) according to the exemplary embodiment of the present disclosure may be electrically connected to each other through the bonding pad 182.

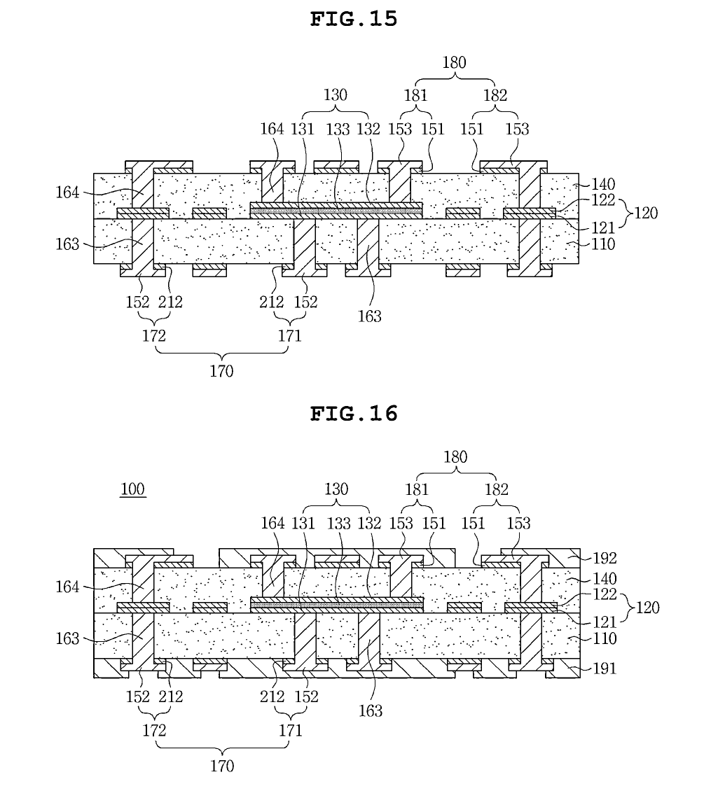

Referring to FIG. 15, the second etching resist 230 and the third etching resist 240 may be removed.

Referring to FIG. 16, the first solder resist layer 191 and the second solder resist layer 192 may be formed.

The first solder resist layer 191 and the second solder resist layer 192 according to the exemplary embodiment of the present disclosure may be formed to protect the second circuit layer 170 and the third circuit layer 180 from external environment. The first solder resist layer 191 and the second solder resist layer 192 may be formed to prevent solder from applying on the circuit layer or the circuit layer from oxidizing while the external components are mounted on the package substrate 100.

The first solder resist layer 191 according to the exemplary embodiment of the present disclosure is formed beneath the first insulating layer 110 to enclose the second circuit layer 170. In this case, the first solder resist layer 191 may be patterned to expose the external connection pad 172.

Further, the second solder resist layer 192 may be formed on the second insulating layer 140 to enclose the third circuit layer 180. In this case, the second solder resist layer 192 may be patterned to expose the bonding pad 182.

The first solder resist layer 191 and the second solder resist layer 192 may be made of a heat resistant covering material.

The exemplary embodiment of the present disclosure describes, by way of example, that the package substrate 100 is provided with the insulating layer having a 3-layer structure and the circuit layer having a two-layer structure. That is, the number of layers of the package substrate 100 may be variously implemented according to the selection of those skilled in the art.

Further, according to the exemplary embodiment of the present disclosure, the circuit layer is formed by applying a tenting method. However, the method of forming a circuit layer is not limited to the tenting method. As the method of forming a circuit layer, any of the methods such as a semi-additive process (SAP) and a modify semi-additive process (MSAP) which may be applied in the circuit board field may be applied.

The package substrate 100 formed according to the exemplary embodiment of the present disclosure has the thin capacitor 130 embedded therein, thereby implementing the noise shielding while forming the thin package substrate 100. Therefore, as the package substrate 100 formed according to the exemplary embodiment of the present disclosure, the thin package substrate on which the memory device is mounted may be applied.

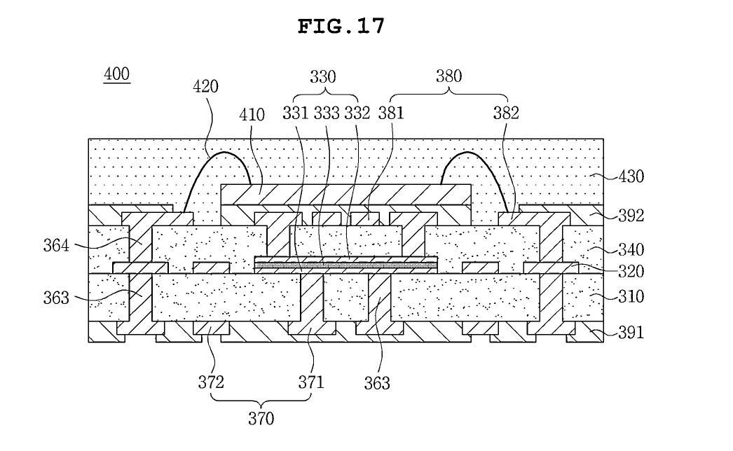

FIG. 17 is an exemplified view illustrating the semiconductor package to which the package substrate according to the exemplary embodiment of the present disclosure is applied.

Referring to FIG. 17, a semiconductor package 400 according to an exemplary embodiment of the present disclosure may include a package substrate 300, a semiconductor device 410, and a molding part 430.

According to the exemplary embodiment of the present disclosure, a first insulating layer 310 and a second insulating layer 340 may be generally made of a composite polymer resin used as an interlayer insulating material. For example, the first insulating layer 310 and the second insulating layer 340 may be made of an epoxy based resin, such as a prepreg, an ajinomoto build up film (ABF), FR-4, and bismaleimide triazine (BT). According to the exemplary embodiment of the present disclosure, the second insulating layer 340 may be formed on the first insulating layer 310.

According to the exemplary embodiment of the present disclosure, the first circuit layer 320 may be formed on the first insulating layer 310.

Further, a second circuit layer 370 may be formed beneath the first insulating layer 310. According to the exemplary embodiment of the present disclosure, the second circuit layer 370 may include a second circuit pattern 371 and an external connection pad 372 electrically connected to external components.

A third circuit layer 380 may be formed on the second insulating layer 340. According to the exemplary embodiment of the present disclosure, the third circuit layer 380 may include a third circuit pattern 381 and a bonding bad 382 electrically connected to the semiconductor device 410.

The first circuit layer 320 to the third circuit layer 380 may be made of a conductive material such as copper. Any material which may be used as a conductive material for a circuit in a circuit board field may be applied to the first circuit layer 320 to the third circuit layer 380 without being limited.

Further, according to the exemplary embodiment of the present disclosure, one of the first circuit layer 320 to the third circuit layer 380 may be a power layer. Further, another layer may be a ground layer.

According to the exemplary embodiment of the present disclosure, a capacitor 330 may be a thin capacitor having a 3-layer structure. According to the exemplary embodiment of the present disclosure, the capacitor 330 may be formed on the first insulating layer 310 and may be formed to be embedded in the second insulating layer 340. The capacitor 330 according to the exemplary embodiment of the present disclosure may include an upper electrode 332, a lower electrode 331, and a dielectric layer 332 formed between the upper electrode 332 and the lower electrode 331.

According to the exemplary embodiment of the present disclosure, the lower electrode 331 of the capacitor 330 may be formed to be partially bonded to the first circuit layer 320. For example, when the first circuit layer 320 is the power layer, the lower electrode 331 of the capacitor 330 may also serve as the power layer.

According to the exemplary embodiment of the present disclosure, the lower electrode 331 and the upper electrode 332 of the capacitor 130 may be made of the conductive material for the circuit. For example, the lower electrode 331 and the upper electrode 332 may be made of copper. The package substrate 300 according to the exemplary embodiment of the present disclosure may have the capacitor 330 embedded therein to shield noises related to electrical signal transmission to the semiconductor device (not illustrated) which is mounted later.

According to the exemplary embodiment of the present disclosure, a first via 363 may penetrate through the first insulating layer 310 to electrically connect the lower electrode 331 or the first circuit layer 320 to the second circuit layer 370. Further, a second via 364 may penetrate through the second insulating layer 340 to electrically connect the upper electrode 332 or the first circuit layer 320 to the third circuit layer 380.

The first via 363 and the second via 364 according to the exemplary embodiment of the present disclosure may be made of the conductive material for the circuit. For example, the first via 363 and the second via 364 may be made of copper (Cu). As such, in the package substrate 300 according to the exemplary embodiment of the present disclosure, the capacitor 330 may be connected to the plurality of first vias 363 and second vias 364, and thus the reactance may be reduced. Therefore, the noise shielding characteristics for an electronic signal may be improved.

A first solder resist layer 391 and a second solder resist layer 392 according to the exemplary embodiment of the present disclosure may be formed to protect an outer layer of the package substrate 300 from external environment. The first solder resist layer 391 and the second solder resist layer 392 may be made of a heat resistant covering material.

The first solder resist layer 391 is formed beneath the first insulating layer 310 to enclose the second circuit layer 370. In this case, the first solder resist layer 391 may be patterned to expose the external connection pad 372. The second solder resist layer 392 is formed on the second insulating layer 340 to enclose the third circuit layer 380. In this case, the second solder resist layer 392 may be patterned to expose the bonding pad 382.

The exemplary embodiment of the present disclosure describes, by way of example, that the package substrate 300 is provided with the insulating layer having a 3-layer structure and the circuit layer having a two-layer structure. That is, the number of layers of the package substrate 300 may be variously implemented according to the selection of those skilled in the art.

According to the exemplary embodiment of the present disclosure, the semiconductor device 410 may be a memory device.

The semiconductor device 410 may be formed on the second solder resist layer 392. In this case, the semiconductor device 410 may be electrically connected to the bonding pad 382 of the third circuit layer 380. For example, the semiconductor device 410 and the bonding pad 382 may be electrically connected to each other through a wire 420.

According to the exemplary embodiment of the present disclosure, an electrical signal of the semiconductor device 410 may be transmitted to the capacitor 330 through the wire 420, the bonding pad 382, and the second via 364. As such, noises of the transmitted electronic signal of the semiconductor device 410 may be shielded by the capacitor 330.

A molding part 430 may be formed to enclose the package substrate 300 and the semiconductor device 410. The molding part 430 may be formed to protect the package substrate 300 and the semiconductor device 410 from external environment. For example, the molding part 430 may be made of an epoxy molding compound (EMC). A kind of the molding part 430 is not also limited to the EMC. Any kind of molding part 430 which may be used in the package field may be applied.

As set forth above, according to the package substrate, the method of manufacturing the same, and the semiconductor package using the same in accordance with the exemplary embodiments of the present disclosure, it is possible to shield the signal noises while keeping the thickness thin by having the thin capacitor embedded in the package substrate.

Further, according to the package substrate, the method of manufacturing the same, and the semiconductor package using the same in accordance with the exemplary embodiments of the present disclosure, it is possible to reduce the process cost and time by simultaneously forming the capacitor and the circuit layer.

In addition, according to the package substrate, the method of manufacturing the same, and the semiconductor package using the same in accordance with the exemplary embodiments of the present disclosure, it is possible to reduce the reactance by connecting the capacitor to the plurality of vias.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A package substrate, comprising:
an insulating layer;
a circuit layer formed on and beneath the insulating layer;
a capacitor formed in the insulating layer and including an upper electrode, a lower electrode, and a dielectric layer formed between the upper electrode and the lower electrode; and
a via connecting the circuit layer to the upper electrode and the lower electrode.

2. The package substrate of claim 1, wherein the insulating layer has a 2-layer structure and includes a first insulating layer and a second insulating layer formed on the first insulating layer, and
the circuit layer has a 3-layer structure and includes a first circuit layer formed on the first insulating layer, a second circuit layer formed beneath the first insulating layer, and a third circuit layer formed on the second insulating layer.

3. The package substrate of claim 2, wherein the capacitor is formed on the first insulating layer and is embedded in the second insulating layer.

4. The package substrate of claim 2, wherein the via includes:
a first via formed on the first insulating layer to connect the lower electrode of the capacitor to the second circuit layer; and
a second via formed on the second insulating layer to connect the upper electrode of the capacitor to the third circuit layer.

5. The package substrate of claim 2, wherein one of the first circuit layer to the third circuit layer is a ground layer and another layer is a power layer.

6. The package substrate of claim 1, further comprising:
a solder resist layer formed to enclose the insulating layer and the circuit layer, except for an area connected to the outside from the circuit layer.

7. A method of manufacturing a package substrate, the method comprising:
preparing a carrier substrate;
forming a first insulating layer on the carrier substrate;
forming a first metal layer on the first insulating layer;
forming a dielectric layer on the first metal layer;
forming a second metal layer on the first metal layer and the dielectric layer;
forming a first circuit layer and a capacitor by patterning the first metal layer and the second metal layer;
forming a second insulating layer on the first insulating layer, a circuit layer, and an upper portion of the capacitor;
removing the carrier substrate;
forming a first via penetrating through the first insulating layer to be connected to the capacitor and a second via penetrating through the second insulating layer to be connected to the capacitor; and
forming a second circuit layer formed beneath the first insulating layer and a third circuit layer formed on the second insulating layer.

8. The method of claim 7, wherein in the forming of the second circuit layer and the third circuit layer, a circuit pattern of a portion of the second circuit layer is connected to the first via and a circuit pattern of a portion of the third circuit layer is connected to the second via.

9. The method of claim 7, wherein one of the first circuit layer to the third circuit layer is a ground layer and another layer is a power layer.

10. The method of claim 7, further comprising:
after the forming of the second circuit layer and the third circuit layer, forming a solder resist layer enclosing the first insulating layer, the second insulating layer, the second circuit layer, and the third circuit layer, except for an area connected to an outside in the second circuit layer and the third circuit layer.

11. The method of claim 7, wherein in the forming of the first circuit layer and the capacitor, the first metal layer beneath the dielectric layer is a lower electrode of the capacitor and the second metal layer on the dielectric layer is an upper electrode of the capacitor.

12. A semiconductor package, comprising:
an insulating layer;
a circuit layer formed on and beneath the insulating layer;
a capacitor formed in the insulating layer and including an upper electrode, a lower electrode, and a dielectric layer formed between the upper electrode and the lower electrode;
a via connecting the circuit layer to the upper electrode and the lower electrode; and
a semiconductor device formed on the insulating layer and electrically connected to the circuit layer.

13. The semiconductor package of claim 12, wherein the insulating layer has a 2-layer structure and includes a first insulating layer and a second insulating layer formed on the first insulating layer, and
the circuit layer has a 3-layer structure and includes a first circuit layer formed on the first insulating layer, a second circuit layer formed beneath the first insulating layer, and a third circuit layer formed on the second insulating layer.

14. The semiconductor package of claim 13, wherein the capacitor is formed on the first insulating layer and is embedded in the second insulating layer.

15. The semiconductor package of claim 13, wherein the via includes:
a first via formed on the first insulating layer to connect the lower electrode of the capacitor to the second circuit layer; and
a second via formed on the second insulating layer to connect the upper electrode of the capacitor to the third circuit layer.

16. The semiconductor package of claim 13, wherein one of the first circuit layer to the third circuit layer is a ground layer and another layer is a power layer.

17. The semiconductor package of claim 12, further comprising:
a solder resist layer formed to enclose the insulating layer and the circuit layer, except for an area connected to the outside in the circuit layer.

18. The semiconductor package of claim 12, wherein the semiconductor device is a memory device.

19. The semiconductor package of claim 12, further comprising:
a molding part formed to enclose the insulating layer, the circuit layer, the capacitor, and the semiconductor device.
